(19) United States
(12) Patent Application Publication
(10) Pub. No.: US 2026/0114150 A1
(43) Pub. Date: Apr. 23, 2026

(54) LIGHT EMITTING DISPLAY DEVICE

(71) Applicant: LG Display Co., Ltd., Seoul (KR)

(72) Inventor: Jaeyoung KWAK, Paju-si (KR)

(73) Assignee: LG Display Co., Ltd., Seoul (KR)

(21) Appl. No.: 19/235,291

(22) Filed: Jun. 11, 2025

(30) Foreign Application Priority Data
Oct. 23, 2024 (KR) 10-2024-0146220

(51) Int. Cl. H10K 59/80; H10K 59/35

(52) U.S. Cl. CPC H10K 59/80523; H10K 59/35

(57) ABSTRACT

A light emitting display device in some examples can include a substrate, an anode electrode, an emission layer, and a cathode electrode. The substrate has a plurality of pixels. The anode electrode is disposed at each pixel. The emission layer is disposed on the anode electrode. The cathode electrode is disposed on the emission layer. The cathode electrode includes a first layer on the emission layer, a second layer on the first layer, and a third layer on the second layer.

### CROSS-REFERENCE TO RELATED APPLICATIONS

This application claims priority to Korean Patent Application No. 10-2024-0146220, filed in the Republic of Korea on Oct. 23, 2024, the entire contents of which is hereby expressly incorporated by reference into the present application.

### BACKGROUND

### Field of the Invention

The present disclosure relates to a light emitting display device.

### Discussion of the Related Art

Recently, a head mount display (HMD) including an organic light emitting diode display has been developed. The HMD is a wearable monitor device for virtual reality (VR) or augmented reality (AR) that is worn in the form of glasses or a helmet so it focuses on a distance close to the user's eyes. Such a head-mounted display can be equipped with a small organic light emitting diode display with a high resolution property.

Particularly, in an ultra-high-density resolution display device having a pixel density of 4K PPI (pixel per inch) or more, since the size of the pixel can be getting smaller, it is needed to improve the structure of the light emitting display device for enhancing the light efficiency so that the light emitting display device can have a brighter and clearer picture or video quality with the same power consumption. In addition, as the pixel size decreases, the light emitted can be concentrated mainly in the frontal direction, which can cause a problem in which the image quality deteriorates at a wide viewing angle. Therefore, there is a need to develop an ultra-high-resolution light emitting display device that can improve light extraction and ensure a wide viewing angle.

### SUMMARY OF THE DISCLOSURE

One or more purposes of the present disclosure, as for solving the problems described above, are to provide a top emission type light emitting display device or a top emission type transparent light emitting display device having a high luminance compared to power consumption.

One or more example embodiments of the present disclosure can provide a top emission type light emitting display device or a top emission type transparent light emitting display device that can operate at low power with a higher brightness at the same power consumption by being configured with a cathode electrode having a structure capable of improved light efficiency.

In some embodiments, the present disclosure can have a cathode electrode with a structure that improves light efficiency while diffusing the light from the emission layer in a viewing angle direction. Therefore, the present disclosure can provide a top emission type light emitting display device or a top emission type transparent light emitting display device with improved a high brightness and wide viewing angle features.

In order to accomplish the above-mentioned purposes of the present disclosure, a light emitting display device according to aspects of the present disclosure comprises a substrate, an anode electrode, an emission layer, and a cathode electrode. The substrate has a plurality of pixels. The anode electrode is disposed at each pixel. The emission layer is disposed on the anode electrode. The cathode electrode is disposed on the emission layer. The cathode electrode includes: a first layer on the emission layer, a second layer on the first layer, and a third layer on the second layer.

In an example of the present disclosure, the first layer includes a first metal material and a second metal material inhibiting agglomeration of the first material.

In an example of the present disclosure, the first metal material includes one of silver (Ag), aluminum (Al), gold (Au), platinum (Pt) and copper (Cu). The second metal material includes magnesium (Mg).

In an example of the present disclosure, the second layer has a smaller atomic size smaller than the second metal material for preventing the second metal material from being diffusing the third layer.

In an example of the present disclosure, the second layer includes lithium fluoride (LiF).

In an example of the present disclosure, the third layer includes a single metal layer including the first metal material.

In an example of the present disclosure, the third layer includes a plurality of grains dispersed with a diameter of 50 Å to 100 Å, the grains being formed by agglomeration of the first metal material.

In an example of the present disclosure, the first layer includes an alloy material of silver (Ag): magnesium (Mg). The third layer includes one of silver (Ag), aluminum (Al), gold (Au), platinum (Pt) and copper (Cu).

In an example of the present disclosure, the first layer has a thickness of 100 Å to 300 Å.

In an example of the present disclosure, the second layer has a thickness of 50 Å to 100 Å.

In an example of the present disclosure, the third layer has a thickness of 300 Å to 500 Å.

In an example of the present disclosure, the light emitting display device further comprises a driving element layer, a light emitting element layer, an encapsulation layer, and a color filter. The driving element layer is disposed on the substrate. The light emitting element layer is disposed on the driving element layer, and including the anode electrode, the emission layer and the cathode electrode. The encapsulation layer is disposed on the light emitting element layer. The color filter layer is disposed on the encapsulation layer.

In an example of the present disclosure, the plurality of pixels includes a first pixel, a second pixel and a third pixel. The third layer in the first pixel includes a first metal material. The third layer in the second pixel includes a second metal material. The third layer in the third pixel includes a third metal material.

In an example of the present disclosure, each of the first metal material, the second metal material and the third metal material includes one of silver (Ag), aluminum (Al), gold (Au), platinum (Pt) and copper (Cu). The first metal material, the second metal material and the third metal material include different metal materials from each other.

In an example of the present disclosure, the first pixel includes a first color filter. The second pixel includes a second color filter different from the first color filter. The third pixel includes a third color filter different from the first color filter and the second color filter.

The light emitting display device according to aspects of the present disclosure can include a multilayer structure of cathode electrodes and an agglomeration layer utilizing the agglomeration properties of metal materials on the top layer. The agglomeration layer can have a structure in which grains or nano-particles of metal material can be dispersed. The surface of the agglomeration layer can be not smooth, but can have rough surface condition. When light emitted from the emission layer located under the agglomeration layer is incident on the agglomeration layer, the light may not be reflected at the interface of the agglomeration layer, but be refracted upward direction. Accordingly, the light extraction efficiency can be improved. In addition, as light incident into the agglomeration layer can pass through the agglomeration layer and can be scattered by a number of grains, and then light emitted through the cathode electrode can be scattered in the direction of the wide viewing angle.

The light emitting display device according to aspects of the present disclosure can have improved light extraction efficiency by the agglomeration layer and can ensure a wide viewing angle. Therefore, in an ultra-high resolution light emitting display device with a small emission area for each pixel, a higher brightness can be provided with the same power consumption, so that the display can be operated with low power consumption.

In addition to the effects of the present disclosure mentioned above, other features and advantages of the present disclosure are described below, or can be clearly understood by those skilled in the art from such descriptions and explanations.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a plane view illustrating a schematic structure of a light emitting display device according to one or more embodiments of the present disclosure.

FIG. 2 is a circuit diagram illustrating a structure of one pixel disposed in a light emitting display device according to an embodiment of the present disclosure.

FIG. 3 is an enlarged plan view illustrating a structure of three pixels sequentially disposed in the light emitting display device according to an embodiment of the present disclosure.

FIG. 4 is a cross-sectional view, cutting along line I-I′ in FIG. 3, for illustrating a structure of one pixel in a light emitting display device according to an embodiment of the present disclosure.

FIG. 5 is a cross-sectional view, enlarging dotted box ‘X’ in FIG. 4, illustrating a structure of a light emitting display device according to a first embodiment of the present disclosure.

FIG. 6 is an enlarged cross-sectional view, cutting along line I-I′ of FIG. 3, for illustrating a structure of one pixel in a light emitting display device according to an embodiment of the present disclosure.

FIG. 7 is a cross-sectional view, enlarging dotted box ‘Y’ in FIG. 6, illustrating a structure of a light emitting display device according to a second embodiment of the present disclosure.

### DETAILED DESCRIPTION OF THE EMBODIMENTS

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these example embodiments are provided so that this disclosure can be sufficiently thorough and complete to assist those skilled in the art to fully understand the scope of the present disclosure. Further, the protected scope of the present disclosure is defined by claims and their equivalents.

The shapes, sizes, ratios, angles, numbers, and the like, which are illustrated in the drawings in order to describe various example embodiments of the present disclosure, are merely given by way of example. Therefore, the present disclosure is not limited to the illustrated details. Like reference numerals refer to like elements throughout the disclosure unless otherwise specified. In the following description, where the detailed description of the relevant known function or configuration can unnecessarily obscure an important point of the present disclosure, a detailed description of such known function of configuration can be omitted.

Reference will now be made in detail to the example embodiments of the present disclosure, examples of which are illustrated in the accompanying drawings. Wherever possible, the same reference numbers will be used throughout the drawings to refer to the same or like parts. In the disclosure, it should be noted that like reference numerals already used to denote like elements in other drawings are used for elements wherever possible. In the following description, when a function and a configuration known to those skilled in the art are irrelevant to the essential configuration of the present disclosure, their detailed descriptions will be omitted. The terms described in the disclosure should be understood as follows.

In the present disclosure, where the terms “comprise,” “have,” “include,” and the like are used, one or more other elements can be added unless the term, such as “only,” is used. An element described in the singular form is intended to include a plurality of elements, and vice versa, unless the context clearly indicates otherwise.

In construing an element, the element is construed as including an error or tolerance range even where no explicit description of such an error or tolerance range is provided.

In the description of the various embodiments of the present disclosure, where positional relationships are described, for example, where the positional relationship between two parts is described using “on,” “over,” “under,” “above,” “below,” “beside,” “next,” or the like, one or more other parts can be located between the two parts unless a more limiting term, such as “immediate(ly),” “direct(ly),” or “close(ly)” is used. For example, where an element or layer is disposed “on” another element or layer, a third layer or element can be interposed therebetween. Further, if a first element is described as positioned “on” a second element, it does not necessarily mean that the first element is positioned above the second element in the figure. The upper part and the lower part of an object concerned can be changed depending on the orientation of the object. Consequently, where a first element is described as positioned “on” a second element, the first element can be positioned “below” the second element or “above” the second element in the figure or in an actual configuration, depending on the orientation of the object.

In describing a temporal relationship, when the temporal order is described as, for example, “after,” “subsequent,” “next,” or “before,” a case which is not continuous can be included unless a more limiting term, such as “just,” “immediate(ly),” or “direct(ly),” is used.

It will be understood that, although the terms “first,” “second,” and the like can be used herein to describe various elements, these elements should not be limited by these terms as they are not used to define a particular order. These terms are used only to distinguish one element from another. For example, a first element could be termed a second element, and, similarly, a second element could be termed a first element, without departing from the scope of the present disclosure.

In describing various elements in the present disclosure, terms such as first, second, A, B, (a), and (b) can be used. These terms are used merely to distinguish one element from another, and not to define a particular nature, order, sequence, or number of the elements. Where an element is described as being “linked”, “coupled,” or “connected” to another element, that element can be directly or indirectly connected to that other element unless otherwise specified. It is to be understood that additional element or elements can be “interposed” between the two elements that are described as “linked,” “connected,” or “coupled” to each other.

It should be understood that the term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship. Further, the term “can” fully encompasses all the meanings and coverages of the term “may” and vice versa.

Hereinafter, a display apparatus according to various embodiments of the present disclosure will be described in detail with reference to the attached drawings. All the components of each display apparatus according to all embodiments of the present disclosure are operatively coupled and configured. Further, wherever possible, the same reference numbers will be used throughout the drawings to refer to the same or like parts.

Since a scale of each of elements shown in the accompanying drawings can be different from an actual scale for convenience of description, the present disclosure is not limited to the scale shown in the drawings.

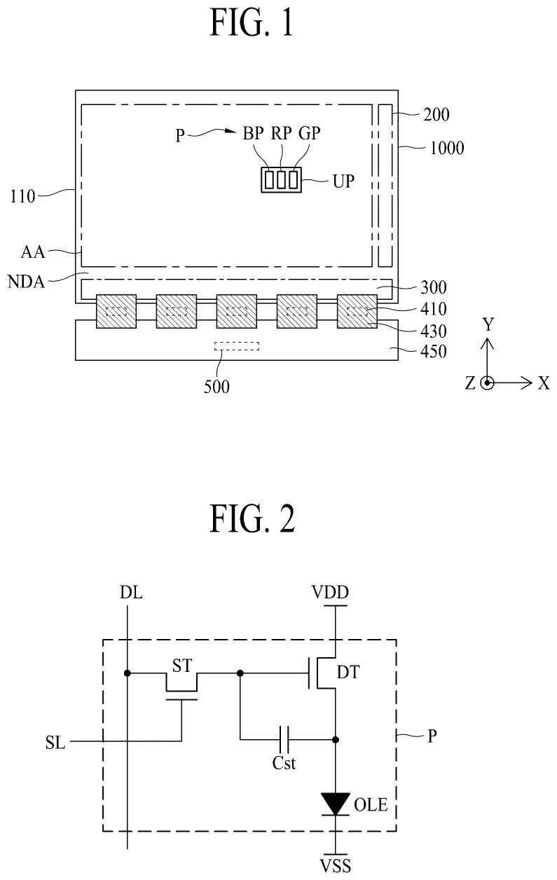

FIG. 1 is a plane view illustrating a schematic structure of a light emitting display device (e.g., electroluminescence display) according to one or more embodiments of the present disclosure. In FIG. 1, X-axis refers to the direction parallel to the scan line, Y-axis refers to the direction of the data line, and Z-axis refers to the height direction of the display device.

Referring to FIG. 1, the electroluminescence display comprises a substrate 110, a gate (or scan) driver 200, a pad portion 300, a source driving IC (Integrated Circuit) 410, a flexible circuit film 430, a circuit board 450, and a timing controller 500.

The substrate 110 can include an electrical insulating material or a flexible material. The substrate 110 can be made of a glass, a metal or a plastic, but it is not limited thereto. When the light emitting display device is a flexible display, the substrate 110 can be made of the flexible material such as plastic. For example, the substrate 110 can include a transparent polyimide material.

The substrate 110 can include a display area AA and a non-display area NDA. The display area AA, which is an area for representing the image information or the video images, can be defined as the majority middle area of the substrate 110, but it is not limited thereto. In the display area AA, a plurality of pixels P are arrayed in a matrix manner. Further, a plurality of scan lines (or gate lines), a plurality of data lines can be disposed as crossing each other. Each of pixels P can be disposed at the crossing area of the scan line running to X-axis and the data line running to Y-axis.

Here, the pixel P can represent any one of color among red, green and blue or red, green, blue or white. A red pixel, a green pixel and a blue pixel can be gathered or a red pixel, a green pixel, a blue pixel and a white pixel can be gathered to form one unit pixel. For example, each of the pixels representing each color can be called as a ‘sub-pixel’, and it can be explained that these ‘sub-pixels’ form one ‘pixel’. As another example, it can be explained that pixels representing each color are called as ‘pixels BP, RP and GP’, and three or four of these ‘pixels’ are gathered to form one ‘unit pixel UP’. Hereinafter, the latter case will be described.

The non-display area NDA, which is an area not representing the video images, can be defined at the circumference areas of the substrate 110 surrounding all or some of the display area AA (or active area). In the non-display area NDA, the gate driver 200 and the pad portion 300 can be formed or disposed.

The gate driver 200 can supply the scan (or gate) signals to the scan lines SL according to the gate control signal received from the timing controller 500 through the pad portion 300. The gate driver 200 can be formed at the non-display area NDA at any one outside of the display area DA on the substrate 110, as a GIP (Gate driver In Panel) type. GIP type means that the gate driver 200 is directly formed on the substrate 110. For example, the gate driver 200 can be configured with shift registers. In the GIP type, the transistors for shift registers of the gate driver 200 are directly formed on the upper surface of the substrate 110.

The pad portion 300 can be disposed in the non-display area NDA at one side edge of the display area AA of the substrate 110. The pad portion 300 can include data pads connected to each of the data lines DL, driving current pads connected to the driving current lines, a high-potential pad receiving a high potential voltage, and a low-potential pad receiving a low potential voltage.

The source driving IC 410 can receive the digital video data and the source control signal from the timing controller 500. The source driving IC 410 can convert the digital video data into the analog data voltages according to the source control signal and then supply that to the data lines. When the source driving IC 410 is made as a chip type, it can be installed on the flexible circuit film 430 as a COF (Chip On Film) or COP (Chip On Plastic) type.

The flexible circuit film 430 can include a plurality of first link lines connecting the pad portion 300 to the source driving IC 410, and a plurality of second link lines connecting the pad portion 300 to the circuit board 450. The flexible circuit film 430 can be attached on the pad portion 300 using an anisotropic conducting film, so that the pad portion 300 can be connected to the first link lines of the flexible circuit film 430.

The circuit board 450 can be attached to the flexible circuit film 430. The circuit board 450 can include a plurality of circuits implemented as the driving chips. For example, the circuit board 450 can be a printed circuit board or a flexible printed circuit board.

The timing controller 500 can receive the digital video data and the timing signal from an external system board through the line cables of the circuit board 450. The timing controller 500 can generate a gate control signal for controlling the operation timing of the gate driver 200 and a source control signal for controlling the source driving IC 410, based on the timing signal. The timing controller 500 can supply the gate control signal to the gate driver 200 and supply the source control signal to the source driving IC 410. Depending on the product types, the timing controller 500 can be integrated with the source driving IC 410 into one driving chip and can be mounted on the substrate 110 to be connected to the pad unit 300.

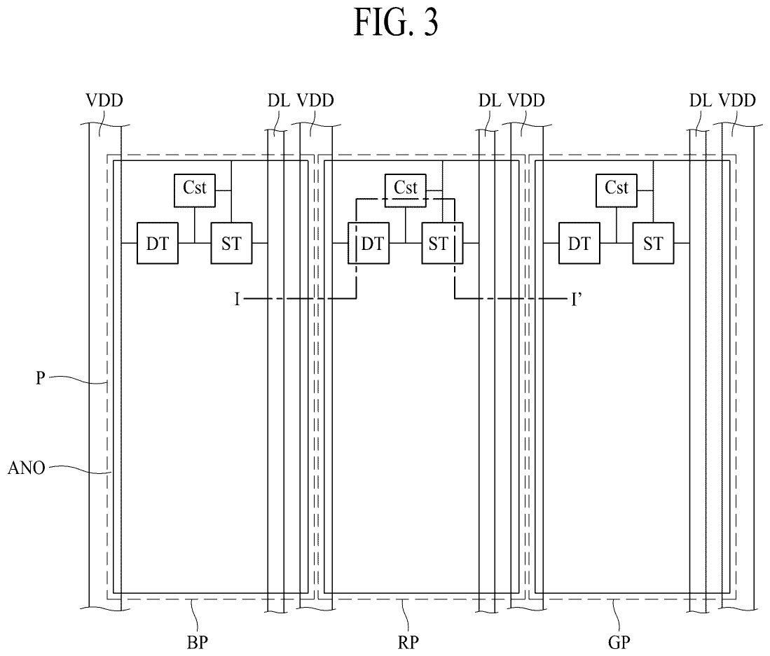

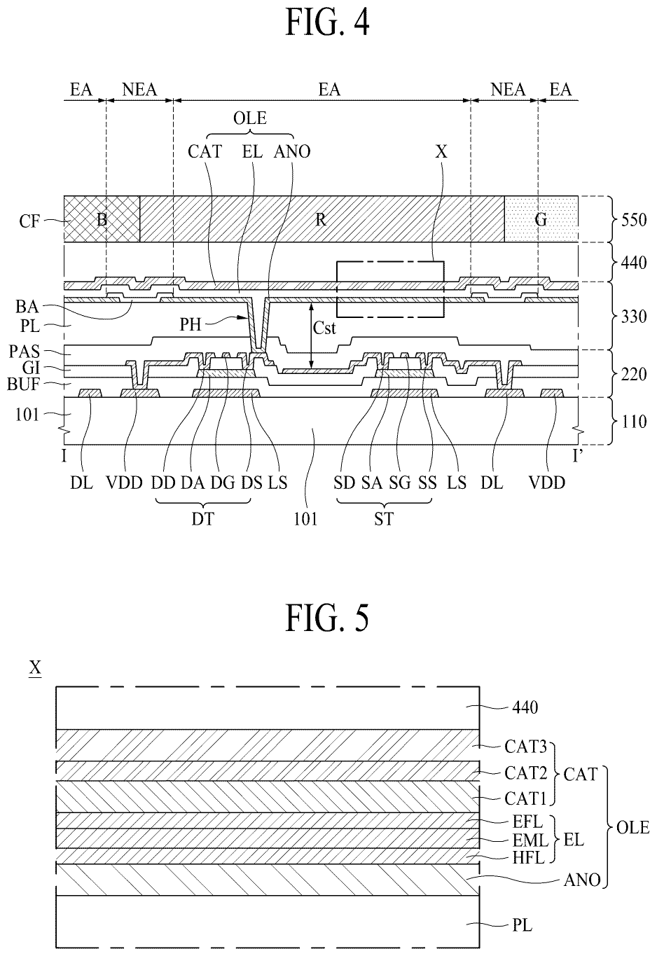

Hereinafter, referring to FIGS. 2 to 4, a detailed structure of a light emitting display device according to an embodiment of the present disclosure will be explained. FIG. 2 is a circuit diagram illustrating a structure of one pixel disposed in a light emitting display device according to an embodiment of the present disclosure. FIG. 3 is an enlarged plan view illustrating a structure of three pixels sequentially disposed in the light emitting display device according to an embodiment of the present disclosure. FIG. 4 is a cross-sectional view, cutting along line I-I′ in FIG. 3, for illustrating a structure of one pixel in a light emitting display device according to an embodiment of the present disclosure.

Referring to FIGS. 2 and 3 at first, each pixel P of the light emitting display according to the present disclosure can be defined by a scan line SL, a data line DL and a driving current line VDD. Each pixel P of the light emitting display can include a switching thin film transistor ST, a driving thin film transistor DT, a light emitting diode OLE and a storage capacitance (or capacitor) Cst. The driving current line VDD can be supplied with a high-level voltage for driving the light emitting diode OLE.

A switching thin film transistor ST and a driving thin film transistor DT can be formed on a substrate 110. For example, the switching thin film transistor ST can be configured to be connected to the scan line SL and the data line DL is crossing. The switching thin film transistor ST can include a gate electrode SG, a semiconductor layer SA, a source electrode SS and a drain electrode SD. The gate electrode SG of the switching thin film transistor ST can be a portion of the scan line SL. The semiconductor layer SA can be disposed as crossing the gate electrode SG. The overlapped portion of the semiconductor layer SA with the gate electrode SG can be defined as the channel area. The source electrode SS can be branched from or connected to the data line DL, and the drain electrode SD can be connected to the driving thin film transistor DT. The source electrode SS can be one side of the semiconductor layer SA from the channel area, and the drain electrode SD can be the other side of the semiconductor layer SA. By supplying the data signal to the driving thin film transistor DT, the switching thin film transistor ST can play a role of selecting a pixel P which would be driven.

The driving thin film transistor DT can play a role of driving the light diode OLE of the selected pixel P by the switching thin film transistor ST. The driving thin film transistor DT can include a gate electrode DG, a semiconductor layer DA, a source electrode DS and a drain electrode DD. The gate electrode DG of the driving thin film transistor DT can be connected to the drain electrode SD of the switching thin film transistor ST. For example, the gate electrode DG of the driving thin film transistor DT can be extended form the drain electrode SD of the switching thin film transistor ST. In the driving thin film transistor DT, the drain electrode DD can be branched from or connected to the driving current line VDD, further, the source electrode DS can be connected to the anode electrode (or pixel electrode) ANO of the light emitting diode (or light emitting element) OLE. The semiconductor layer DA can be disposed as crossing over the gate electrode DG. In the semiconductor layer DA, the overlapped portion with the gate electrode DG can be defined as a channel area. The source electrode DS can be connected at one side of the semiconductor layer DA around the channel area, and the drain electrode DD is connected to the other side of the semiconductor layer DA. A storage capacitance (or, capacitor) Cst can be disposed between the gate electrode DG of the driving thin film transistor DT and the anode electrode ANO of the light emitting diode OLE.

The light emitting diode OLE can generate light according to the current controlled by the driving thin film transistor DT. The driving thin film transistor DT can control the amount of current flowing from the driving current ling VDD to the light emitting diode OLE according to the voltage difference between the gate electrode DG and the source electrode DS.

The light emitting diode OLE can include an anode electrode ANO, an emission layer, and a cathode electrode. The light emitting diode OLE can emit lights according to the current controlled by the driving thin film transistor DT. In other words, the light emitting diode OLE can provide an image by emitting light according to the current controlled by the driving thin film transistor DT. The anode electrode ANO of the light emitting diode OLE can be connected to the source electrode DS of the driving thin film transistor DT. The cathode electrode (or, common electrode) can be low-power line VSS supplied with the low-potential voltage. Therefore, the light emitting diode OLE can be driven by the electric current flown from the driving current line VDD to the low power line VSS controlled by the driving thin film transistor DT.

A plurality of pixels P can be arrayed on the substrate 110. For example, along the horizontal direction, a red pixel RP, a green pixel GP and a blue pixel BP can be sequentially arrayed and disposed. The combination of the red pixel RP, the green pixel GP and the blue pixel BP can configure one unit pixel UP. In another case, the red pixel, the green pixel, the white pixel and the blue pixel can be sequentially arrayed along the horizontal direction. The red pixel, the green pixel, the white pixel and the blue pixel can form a unit pixel. FIG. 3 shows that three pixels, including a red pixel RP, a green pixel GP and a blue pixel BP are sequentially arrayed along the horizontal direction.

Referring to FIG. 4, a cross-sectional structure of the light emitting display device according to an embodiment of the present disclosure will be explained. FIG. 4 is a cross-sectional view along to cutting line I-I′ in FIG. 3, for illustrating a structure of one pixel in a light emitting display device according to an embodiment of the present disclosure. A light emitting display device can include a substrate 110, a driving element layer 220, a light emitting element layer 330, an encapsulation layer 440 and a color filter layer CF. The driving element layer 220 can include a plurality of thin layers formed on the substrate 110. The driving element layer 220 can include a switching thin film transistor ST and a driving thin film transistor DT.

On the substrate 110, a data line DL, a driving current line VDD and a light shielding layer LS can be formed. The light shielding layer LS can be disposed in an island shape spaced apart from the data line DL and the driving current ling VDD by a predetermined distance and overlapping the semiconductor layers SA and DA. In some cases, the light shielding layer LS can be omitted.

A buffer layer BUF is deposited on entire surface of the substrate 110 as covering the driving current line VDD, the data line DL and the light shielding layer LS. On the buffer layer BUF, the semiconductor layer SA of the switching thin film transistor ST and the semiconductor layer DA of the driving thin film transistor DT are formed. The switching thin film transistor ST and the driving thin film transistor DT are formed on the buffer layer BUF. It is preferable that the channel areas in the semiconductor layers SA and DA overlap with the light shielding layer LS.

A gate insulating layer GI is deposited on the substrate 110 as covering the semiconductor layers SA and DA. A gate electrode SG overlapping with the semiconductor layer SA of the switching thin film transistor ST and the gate electrode DG overlapping with the semiconductor layer DA of the driving thin film transistor DT are formed on the gate insulating layer GI. In addition, at both sides of the gate electrode SG of the switching thin film transistor ST, a source electrode SS contacting one side of the semiconductor layer SA while being spaced apart from the gate electrode SG, and a drain electrode SD contacting the other side of the semiconductor layer SA are formed. Further, at both sides of the gate electrode DG of the driving thin film transistor DT, a source electrode DS contacting one side of the semiconductor layer DA while being spaced apart from the gate electrode DG, and a drain electrode DD contacting the other side of the semiconductor layer DA are formed.

The gate electrodes SG and DG and the source-drain electrodes SS-SD and DS-DD are formed on the same layer, but are spatially and electrically separated from each other. The source electrode SS of the switching thin film transistor ST can be connected to the data line DL via a contact hole penetrating the gate insulating layer GI. Further, the drain electrode DD of the driving thin film transistor DT can be connected to the driving current line VDD via another contact hole penetrating the gate insulating layer.

A passivation layer PAS is deposited on the substrate 110 as covering the thin film transistors ST and DT. The passivation layer PAS can be made of an inorganic material such as silicon oxide or silicon nitride.

The light emitting element layer 330 is formed on the driving element layer 220. The light emitting element layer 330 can include a planarization layer PL and a light emitting diode OLE. The planarization layer PL can be a layer used to flatten the uneven surface of the substrate 110 on which the thin film transistors ST and DT are formed. In order to equalize or compensate the height difference due to the uneven surface condition, the planarization layer PL can be formed of an organic material. A pixel contact hole PH can be formed at the passivation layer PAS and the planarization layer PL to expose a portion of the source electrode DS of the driving thin film transistor DT.

An anode electrode (or, pixel electrode) ANO can be formed on the top surface of the planarization layer PL. The anode electrode ANO can be connected to the source electrode DS of the driving thin film transistor DT via a pixel contact hole PH. The anode electrode ANO can have different structure and configuring elements according to the emission type of the light emitting diode OLE. For example, in the case of a bottom emission type that provides lights in the direction of the substrate 110, it can be formed of a transparent conductive material. For another example, in the case of a top emission type that provides lights in the upward direction facing the substrate 110, it can be formed of a metal material having excellent light reflectance. Otherwise, for the case of top emission type emitting light to the upper direction opposite the substrate 110, a reflective layer formed of a metal material with excellent light reflectance can be further included below or above the transparent layer formed of a transparent conductive material. For example, the anode electrode ANO can include any one metal material such as silver (Ag), aluminum (Al), magnesium (Mg), calcium (Ca), gold (Au), copper (Cu), molybdenum (Mo) and titanium (Ti) or alloy metal material thereof.

A bank BA is formed on the top surface of the substrate 110 having the anode electrode ANO. The bank BA is preferably an insulating layer made of an inorganic material or an organic material. Hereinafter, a case made of an in organic material will be described. The bank BA covers the circumferential areas of the anode electrode ANO, and exposes most of the middle area. The middle area exposed from the bank BA is defined as an emission area EA, and the area covered by bank BA is defined as a non-emission area NEA.

An emission layer EL is disposed on the anode electrode ANO and bank BA. The emission layer EL can be deposited on entire of the display area AA of the substrate 110 as covering the anode electrode ANO and the bank BA. For an example, the emission layer EL can include at least two emission parts for generating white light. In detail, the emission layer EL can include a first emission part and a second emission part vertically stacked for generating white light by mixing the first light from the first emission part and the second light from the second emission part.

For another example, the emission layer EL can include any one of a blue emission part, a green emission part, and a red emission part for generating light corresponding to a color set in each pixel. Further, the light emitting diode OLE can include a functional layer for improving light emitting efficiency and/or lifetime of the emission layer EL.

A cathode electrode (or common electrode) CAT is deposited on the entire surface of the substrate 110 on which the emission layer is formed. The cathode electrode CAT is deposited to make surface contact with the emission layer EL. The cathode electrode CAT is formed over the entire substrate 110 to be commonly connected to the emission layer EL deposited in all pixels. In the case of the top emission type, the cathode electrode CAT can include a transparent conductive material with a thickness of 2,000 Å or more.

For the top emission type, the cathode electrode CAT can include transparent conductive material. For example, the cathode electrode CAT can be made of a transparent conductive material such as indium-tin-oxide (ITO) or indium-zinc-oxide (IZO). Alternatively, the cathode electrode CAT can include a thin metal such as aluminum (Al), magnesium (Mg), calcium (Ca), silver (Ag) or an alloy or combination thereof (e.g., aluminum-magnesium alloy (AlMg)). It can be formed to have light-transmitting characteristics by forming it with a thin thickness in a range of 20 Å to 300 Å. The present disclosure can be related to the top emission type light emitting display device.

An encapsulation layer 440 is stacked on the light emitting element 220. The encapsulation layer 440 can have a single-layer structure made of an inorganic material, or a multi-layer structure in which several inorganic layers are sequentially stacked. As another example, the encapsulation layer 440 can have a structure in which an inorganic layer, an organic layer and an inorganic layer are continuously stacked. Here, for convenience of description, the encapsulation layer 440 made of a single inorganic layer will be used for explanation. The encapsulation layer 440 can be called a capping layer. In some cases, the encapsulation layer 440 can have a structure in which a capping layer and an organic encapsulation layer can be stacked.

A color filter layer 550 is stacked on the encapsulation layer 440. In the color filter layer 550, a plurality of color filters CF can be arranged in a matrix manner to correspond to the arrangement of the pixels P. The color filter CF can be disposed with a structure in which one of a red color filter, a green color filter and a blue color filter is assigned to each pixel P. As another example, the color filter CF can be disposed with a structure in which one of a red color filter, a white color filter, a green color filter and a blue color filter is allocated to each pixel P. Hereinafter, for convenience of description, a case, in which the color filter CF includes a red color filter R, a green color filter G and a blue color filter B, representing the triple primary color light, is used for explanation.

For the case of the top emission type, lights emitted from the emission layer EL of the light emitting diode OLE including the anode electrode ANO, the emission layer EL and the cathode electrode CAT sequentially stacked each other, can be provided to the outside of the display device through the cathode electrode CAT. In this case, it is required to form the anode electrode ANO with a thickness of 2,000 Å to 3,000 Å using a metal material with excellent light reflectance. Further, the cathode electrode CAT can preferably be made of a transparent conductive material or, a semi-transparent conductive material.

For the case that the cathode electrode CAT is made of a semi-transparent conductive material, some of lights reflected from the anode electrode ANO can pass through the cathode electrode CAT, and the rest can be reflected and directed to the anode electrode ANO. Lights toward the anode electrode ANO can be reflected back from the anode electrode ANO, and emitted through the cathode electrode CAT. By repeatedly repeating the reflection process between the anode electrode ANO and the cathode electrode CAT, lights can be extracted through the cathode electrode CAT. As the reflection processes can be repeated, a loss of light can occur.

The present disclosure provides a structure for reducing the processes of repeated reflection between the anode electrode ANO and the cathode electrode CAT, and as much light as possible can be emitted to the outside through the cathode electrode CAT.

### First Embodiment

Hereinafter, referring to FIG. 5, a first embodiment of the present disclosure will be explained. FIG. 5 is a cross-sectional view, enlarging dotted box ‘X’ in FIG. 4, illustrating a structure of a light emitting display device according to the first embodiment of the present disclosure.

Referring to FIG. 5, a light emitting diode OLE can be disposed on the planarization layer PL. The light emitting diode OLE can have a structure in which an anode electrode ANO, an emission layer EL and a cathode electrode CAT can be stacked sequentially.

Since the light emitting display device according to the first embodiment of the present disclosure is a top emission type light emitting display, it is preferable that the anode electrode ANO can be formed of a metal material having excellent light reflectance. For an example, the anode electrode ANO can be made of a metal material with excellent light reflectance, such as silver (Ag), aluminum (Al), magnesium (Mg), calcium (Ca), gold (Au), copper (Cu), molybdenum (Mo), or titanium (Ti), or an alloy of them.

The emission layer EL can be deposited on the anode electrode ANO. The emission layer EL can have a structure in which a hole functional layer HFL, an emitting material layer EML and an electron functional layer EFL, stacking sequentially each other. The hole functional layer HFL can be a functional layer for transmitting holes supplied from the anode electrode ANO to the emitting material layer EML. The electron functional layer EFL can be a functional layer for transmitting electrons supplied from the cathode electrode CAT to the emitting material layer EML. The emitting material layer EML can include a light emitting material in which holes and electrons meet to form excitons, and lights are emitted as the excitons return to the ground state from the excitation state.

The cathode electrode CAT can be formed on the emission layer EL. For the case of top emission type light emitting display device, the cathode electrode CAT can be made of a transparent material. For example, as the cathode electrode is made of a metal layer with a thickness of 1,000 Å (100 nm) or less, the lights can transmit the metal layer. Some of lights which enter into a metal layer can be refracted and the rests can be reflected. Lights reflected from the metal layer can be mostly caused by the photoelectric effect. The photoelectric effect can occur within a thickness of 1,000 Å on the surface of the metal layer. When the thickness of the metal layer can be less than 1,000 Å, most of the lights incident into the metal layer can be refracted and can be transmitted. For example, the cathode electrode CAT can be formed by depositing any one metal material including silver (Ag), aluminum (Al), gold (Au), platinum (Pt), copper (Cu), and magnesium (Mg) or an alloy material thereof with a thickness of 100 Å to 1,000 Å.

More details, the cathode electrode CAT can have a structure in which a first cathode layer CAT1, a second cathode layer CAT2 and a third cathode layer CAT3 can be sequentially stacked. The first cathode layer CAT1 can be made of an alloy of silver (Ag) and magnesium (Mg) or an alloy of aluminum (Al) and magnesium (Mg). In the case of the alloys, the metal layer can maintain a thin film shape in which molecules of the metal elements may not agglomerate to form grains. For example, the first cathode layer CAT1 can be made by depositing silver-magnesium alloy (AgMg) with a thickness of 100 Å to 300 Å.

It is preferable that the second cathode layer CAT2 can be formed of a material that can prevent magnesium (Mg) contained in the first cathode layer CAT1 from diffusing into the third cathode layer CAT3 deposited on top of the second cathode layer CAT2. For example, the second cathode layer CAT2 can be formed of a transparent conductive inorganic material such as lithium fluoride (LiF). In particular, since lithium fluoride can have an atomic structure smaller than that of magnesium, it can prevent magnesium atoms from diffusing into the third cathode layer CAT3 through the second cathode layer CAT2. The second cathode layer CAT2 can be formed by depositing lithium fluoride (LiF) to a thickness of 50 Å to 100 Å.

The third cathode layer CAT3 can be formed of a single metal material of any one of silver (Ag), aluminum (Al), gold (Au), platinum (Pt) and copper (Cu). The third cathode layer CAT3 can be a metal layer having a plurality of grains dispersed on the top surface due to agglomeration of the metal material. For example, when silver (Ag) can be deposited on the second cathode layer CAT2, a silver (Ag) thin layer having a plurality of grains with a diameter of 50 Å to 100 Å can be formed by self-agglomeration. The third cathode layer CAT3 can be formed by depositing a metal material of any one of silver (Ag), aluminum (Al), gold (Au), platinum (Pt) and copper (Cu) with a thickness of 300 Å to 500 Å.

It is not limited to that the third cathode layer CAT3 is made of a single metal material such as silver (Ag), aluminum (Al), gold (Au), platinum (Pt) and copper (Cu). The third cathode layer CAT3 can be characterized by being formed with a metal thin layer containing a plurality of grains. For another example, by depositing an alloy including nickel (Ni) and/or platinum (Pt), the third cathode layer CAT3 can be formed in which a large number of grains can be dispersed.

When a voltage difference occurs between the anode electrode ANO and the cathode electrode CAT of the light emitting diode OLE, lights can be emitted from the emission layer EL. Since the anode electrode ANO can be a metal material with excellent light reflectance, all lights generated from the emission layer EL can be reflected by the anode electrode ANO and directed to the cathode electrode CAT.

Since the total thickness of the cathode electrode CAT formed by sequentially stacking the first cathode layer CAT1, the second cathode layer CAT2 and the third cathode layer CAT3 can be 450 Å to 700 Å, most of the lights transmit through the cathode electrode CAT. Hereinafter, the mechanism by which lights reflected from the anode electrode ANO pass through the cathode electrode CAT will be described in detail.

Since the thickness of the first cathode layer CAT1 is 100 Å to 300 Å, most of lights can transmit through the first cathode layer CAT1. Some of the lights can be reflected from the lower surface of the first cathode layer CAT1. However, the reflected lights can be re-reflected again by the anode electrode ANO and enter into the first cathode layer CAT1.

Lights passing through the first cathode layer CAT1 can enter into the second cathode layer CAT2. Since the thickness of the second cathode layer CAT2 can be 50 Å to 100 Å, most of the lights can transmit through the second cathode layer CAT2. Some of the lights can be reflected at the interface between the first cathode layer CAT1 and the second cathode layer CAT2. However, the reflected lights can be re-reflected by the anode electrode ANO, pass through the first cathode layer CAT1 and then enter into the second cathode layer CAT2.

Lights passing through the second cathode layer CAT2 can enter into the third cathode layer CAT3. Since the thickness of the third cathode layer CAT3 can be 300 Å to 500 Å, most of the lights can transmit through the third cathode layer CAT3. Some of the lights can be reflected at the interface between the second cathode layer CAT2 and the third cathode layer CAT3. However, the reflected lights can be re-reflected again by the anode electrode ANO, pass through the first cathode layer CAT1 and the second cathode layer CAT2, and then enter into the third cathode layer CAT3.

The third cathode layer CAT3 can include a plurality of grains on the top surface. Therefore, lights entering into the third cathode layer CAT3 can be emitted out from the top surface of the third cathode layer CAT3 while being diffusely reflected at the surface of the grains.

Lights generated from the emission layer EL can be repeatedly reflected between the anode electrode ANO and the cathode electrode CAT. In particular, lights satisfying the total reflection condition can be dissipated into heat energy during the process of repeated reflection between the anode electrode ANO and the cathode electrode CAT. As a result, the light extraction efficiency from the emission layer EL can be reduced.

However, according to the present disclosure, the cathode electrode CAT can include three different materials and made of metal layers with different refractive indices, so the total reflection conditions may not be the same but have various conditions. Therefore, the light loss due to total reflection can be reduced and light extraction efficiency can be improved or enhanced. In addition, since the third cathode layer CAT3 can have a structure in which a plurality of grains is dispersed, the lower surface of the third cathode layer CAT3 may not be smooth but can have a finely uneven surface condition. Therefore, the total reflection angle of the lower surface of the third cathode layer CAT3 can be not uniformed over the entire surface area. Therefore, the amount of light refracted and transmitted rather than reflected can be increased. Accordingly, the light extraction efficiency can be further increased when the third cathode layer CAT3 has a grain structure compared to when the third cathode layer CAT3 does not have a grain structure.

Further, when lights being incident at the lower surface of the third cathode layer CAT3 can be refracted into the third cathode layer CAT3, the refractive angles can be various due to the grains. When lights entering into the third cathode layer CAT3, they can be scattered in various directions. As a result, the amount of light returning downward due to total reflection on the upper surface of the third cathode layer CAT3 can be remarkably reduced. In addition, when lights are emitted from the top surface of the third cathode layer CAT3, the scattering angle can be wide, so that lights can be emitted out with wide viewing angle. Therefore, the light emitting display device according to the present disclosure can have a feature of a wide viewing angle even without a separated scattering structure such as a lens.

Due to the three-layered structure of the cathode electrode CAT according to the first embodiment of the present disclosure, in particular the topmost metal layer having the grain structure, the light extracting efficiency can be enhanced. That means, the light emitting display device according to the present disclosure can provide brighter luminescence with the same power consumption, or can reduce power consumption with the same brightness. Further, the scattering effect due to the grain structure can ensure the wide viewing angle feature without any additional elements.

On the contrary, when all layers of the cathode electrode CAT are formed with the grain structure, moisture or foreign material can penetrate through the gaps between grains, so that the emitting material layer EML disposed under the cathode electrode CAT can be damaged. Therefore, it is not desirable for the entire cathode electrode CAT to have the grain structure.

As the first cathode layer CAT1 can include a material such as magnesium that inhibits self-agglomeration of metal material, the first cathode layer CAT1 may not have grain structure formed by the agglomeration. The first cathode layer CAT1 can include any material other than magnesium as long as it can inhibit self-agglomeration. When any metal layer having the grain structure such as the third cathode layer CAT3 is directly deposited on the first cathode layer CAT1, magnesium included in the first cathode layer CAT1 can diffuse into the third cathode layer CAT3. Therefore, the self-agglomeration can be hindered by the diffused magnesium, so that the third cathode layer CAT3 may not have the grain structure.

In order to ensure that the third cathode layer CAT3 has a grain structure, it is preferable to form a second cathode layer CAT2 for preventing diffusion of magnesium between the first cathode layer CAT1 and the third cathode layer CAT3. In particular, it is preferable that the second cathode layer CAT2 can be formed of a material having an atomic size smaller than that of magnesium atoms so as to prevent diffusion of magnesium.

### Second Embodiment

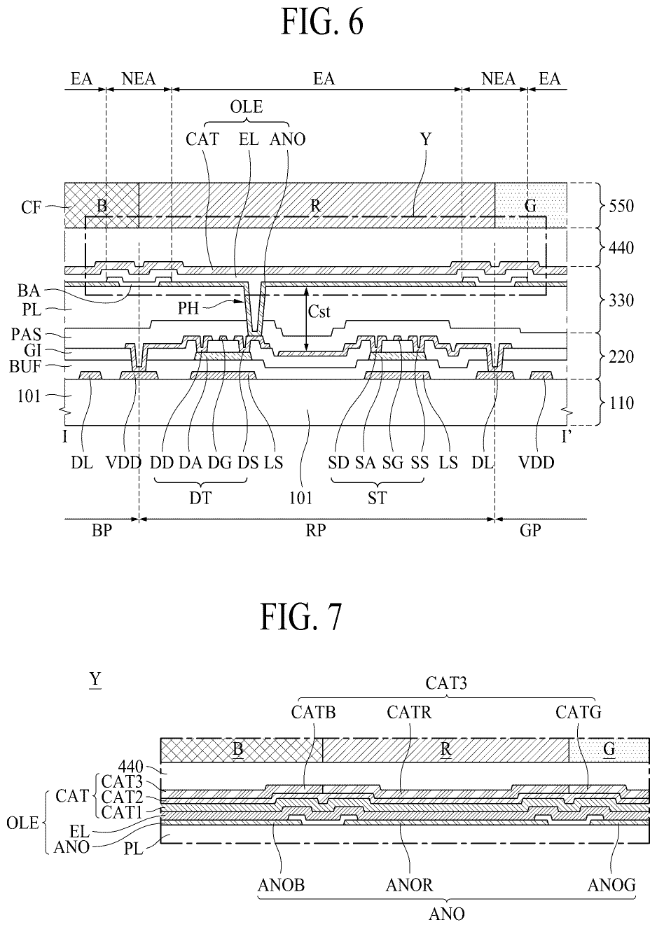

Hereinafter, referring to FIGS. 6 and 7, a light emitting display device according to a second embodiment of the present disclosure will be explained. FIG. 6 is an enlarged cross-sectional view, cutting along line I-I′ of FIG. 3, for illustrating a structure of one pixel in a light emitting display device according to an embodiment of the present disclosure. FIG. 7 is a cross-sectional view, enlarging dotted box ‘Y’ in FIG. 6, illustrating a structure of a light emitting display device according to the second embodiment of the present disclosure.

The light emitting display device shown in FIG. 6 can be a cross-sectional view cutting along the line I-I′ in FIG. 3. Therefore, the plan structure of the second embodiment can be same with that of the first embodiment. For the second embodiment, the cathode structure CAT can have different structure from that of the first embodiment in the cross-sectional view.

Referring to FIG. 6, the light emitting display device can comprise a substrate 110, a driving element layer 220, a light emitting element layer 330, an encapsulation layer 440 and a color filter layer 550. For the overall structure, it can be same with the structure described referring to FIG. 4. Therefore, the description of the same structure may not be duplicated or briefly explained. In the second embodiment, the cross-sectional structure of three pixels arranged in succession can be described as cutting along the line I-I′ of FIG. 3.

A red pixel RP, a green pixel GP and a blue pixel BP can be arranged continuously. Here, the red pixel RP can be a first pixel, the green pixel GP can be a second pixel, and the blue pixel BP can be a third pixel. Each of pixels can include light emitting diode OLE. Each of pixels can have color filter for providing an allocated color to the pixel. For example, a red color filter R can be allocated to the red pixel RP, a green color filter G can be allocated to the green pixel GP, and a blue color filter B can be allocated to the blue pixel BP.

Each light emitting diode OLE disposed each pixel can have the same structure. The difference can be on the structure of the cathode electrode CAT. The structure of the cathode electrode CAT can be explained as referring to FIG. 7, which is an enlarged cross-sectional view of the light emitting diode OLE.

Referring to FIG. 7, the red pixel RP can include a red anode electrode ANOR, an emission layer EL and a cathode electrode CAT which are sequentially stacked. The green pixel GP can include a green anode electrode ANOG, the emission layer EL and the cathode electrode CAT. The blue pixel BP can include a blue anode electrode ANOB, the emission layer EL and the cathode electrode CAT.

The red anode electrode ANOR, the green anode electrode ANOG and the blue anode electrode ANOB can be separated from each other, and any one can be disposed at each pixel. A bank BA can be disposed at the boundaries of the red anode electrode ANOR, the green anode electrode ANOG and the blue anode electrode ANOB. The exposed portions of the anode electrode not covered by the bank BA can be defined as the emission area EA.

The emission layer EL can be deposited on the red anode electrode ANOR, the green anode electrode ANOG, the blue anode electrode ANOB and the bank BA. The emission layer EL can include a material emitting white light, and can be deposited one sheet layer covering entire surface of the substrate 110. However, it is not limited thereto. A red emission layer can be disposed within the red pixel RP, a green emission layer can be disposed within the green pixel GP, and a blue emission layer can be disposed within the blue pixel BP.

The cathode electrode CAT can be deposited on the emission layer EL. The cathode electrode CAT can include a first cathode layer CAT1, a second cathode layer CAT2 and a third cathode layer CAT3 which are sequentially stacked. Here, the first cathode layer CAT1 can be deposited as covering the red pixel RP, the green pixel GP and the blue pixel BP together. The first cathode layer CAT1 can be made of the same material with the same thickness, as the first embodiment.

The second cathode layer CAT2 can be deposited as covering the red pixel RP, the green pixel GP and the blue pixel BP together. The second cathode layer CAT2 can be made of the same material with the same thickness, as the first embodiment.

The third cathode layer CAT3 can be formed separately for each pixel on the second cathode layer CAT2. For example, a red cathode layer CATR can be deposited within the red pixel RP, a green cathode layer CATG can be deposited within the green pixel GP, and a blue cathode layer CATB can be deposited within the blue pixel BP.

The red cathode layer CATR can be a single metal layer including any one of silver (Ag), aluminum (Al), gold (Au), platinum (Pt) and copper (Cu). The green cathode layer CATG can be another single metal layer including any one of silver (Ag), aluminum (Al), gold (Au), platinum (Pt) and copper (Cu), and different from the red cathode layer CATR. The blue cathode layer CATB can be further another single metal layer including any one of silver (Ag), aluminum (Al), gold (Au), platinum (Pt) and copper (Cu), and different from the red cathode layer CATR and the green cathode layer CATG.

For example, the red cathode layer CATR can include a single metal layer of aluminum (Al) deposited with a thickness of 300 Å to 500 Å. The green cathode layer CATG can include a single metal layer of silver (Ag) deposited with a thickness of 300 Å to 500 Å. The blue cathode layer CATB can include a single metal layer of gold (Au) deposited with a thickness of 300 Å to 500 Å.

When the third cathode layer CAT3 can be formed with a different metal material for each color pixel, the conditions for forming the grain structure, such as grain size, surface roughness and number of pores between grains, can be varied depending on the metal material. Therefore, the grain structure can be selected or adjusted to have suitable light scattering characteristics depending on the wavelength of light emitted from each color pixel.

Due to the three-layered structure of the cathode electrode CAT according to the second embodiment of the present disclosure, in particular the topmost metal layer having the grain structure, the light extracting efficiency can be enhanced. That means, the light emitting display device according to the present disclosure can provide brighter luminescence with the same power consumption, or can reduce power consumption with the same brightness. Further, the scattering effect due to the grain structure can ensure the wide viewing angle feature without any additional elements. Furthermore, in the second embodiment, by using metal materials with different conditions (grain size, gap size etc.) for each color pixel, scattering features and light extraction efficiency suitable for the wavelength of the emitting light can be acquired.

The features, structures, effects and so on described in the above example embodiments of the present disclosure are included in at least one example embodiment of the present disclosure, and are not necessarily limited to only one example embodiment. Furthermore, the features, structures, effects and the like explained in at least one example embodiment can be implemented in combination or modification with respect to other example embodiments by those skilled in the art to which this disclosure is directed. Accordingly, such combinations and variations should be construed as being included in the scope of the present disclosure.

It will be apparent to those skilled in the art that various substitutions, modifications, and variations are possible within the scope of the present disclosure without departing from the spirit and scope of the present disclosure. Therefore, it is intended that embodiments of the present disclosure cover the various substitutions, modifications, and variations of the present disclosure, provided they come within the scope of the appended claims and their equivalents. These and other changes can be made to the embodiments in light of the above detailed description. In general, in the following claims, the terms used should not be construed to limit the claims to the specific example embodiments disclosed in the specification and the claims, but should be construed to include all possible embodiments along with the full scope of equivalents to which such claims are entitled. Accordingly, the claims are not limited by the disclosure.

What is claimed is:

1. A light emitting display device comprising:
a substrate having a plurality of pixels;
an anode electrode at each pixel;
an emission layer on the anode electrode; and
a cathode electrode on the emission layer,
wherein the cathode electrode includes:
a first layer on the emission layer;
a second layer on the first layer; and
a third layer on the second layer.

2. The light emitting display device according to claim 1, wherein the first layer of the cathode electrode includes:
a first metal material; and
a second metal material inhibiting agglomeration of the first material.

3. The light emitting display device according to claim 2, wherein the first metal material includes one of silver (Ag), aluminum (Al), gold (Au), platinum (Pt) and copper (Cu), and
wherein the second metal material includes magnesium (Mg).

4. The light emitting display device according to claim 2, wherein the second layer of the cathode electrode has a smaller atomic size smaller than the second metal material for preventing the second metal material from diffusing the third layer of the cathode electrode.

5. The light emitting display device according to claim 3, wherein the second layer of the cathode electrode includes lithium fluoride (LiF).

6. The light emitting display device according to claim 2, wherein the third layer of the cathode electrode includes a single metal layer including the first metal material.

7. The light emitting display device according to claim 6, wherein the third layer of the cathode electrode includes a plurality of grains dispersed with a diameter of 50 Å to 100 Å, the plurality of grains being formed by agglomeration of the first metal material.

8. The light emitting display device according to claim 1, wherein the first layer of the cathode electrode includes an alloy material of silver (Ag): magnesium (Mg), and
wherein the third layer of the cathode electrode includes one of silver (Ag), aluminum (Al), gold (Au), platinum (Pt) and copper (Cu).

9. The light emitting display device according to claim 1, wherein the first layer of the cathode electrode has a thickness of 100 Å to 300 Å.

10. The light emitting display device according to claim 1, wherein the second layer of the cathode electrode has a thickness of 50 Å to 100 Å.

11. The light emitting display device according to claim 1, wherein the third layer of the cathode electrode has a thickness of 300 Å to 500 Å.

12. The light emitting display device according to claim 1, further comprising:
a driving element layer disposed on the substrate;
a light emitting element layer disposed on the driving element layer, and including the anode electrode, the emission layer and the cathode electrode;
an encapsulation layer on the light emitting element layer; and
a color filter layer on the encapsulation layer.

13. The light emitting display device according to claim 12, wherein the plurality of pixels includes a first pixel, a second pixel and a third pixel,
wherein the third layer of the cathode electrode in the first pixel includes a first metal material,
wherein the third layer of the cathode electrode in the second pixel includes a second metal material, and
wherein the third layer of the cathode electrode in the third pixel includes a third metal material.

14. The light emitting display device according to claim 13, wherein each of the first metal material, the second metal material and the third metal material includes one of silver (Ag), aluminum (Al), gold (Au), platinum (Pt) and copper (Cu), and
wherein the first metal material, the second metal material and the third metal material include different metal materials from each other.

15. The light emitting display device according to claim 13, wherein the first pixel includes a first color filter,
wherein the second pixel includes a second color filter different from the first color filter, and
wherein the third pixel includes a third color filter different from the first color filter and the second color filter.

16. The light emitting display device according to claim 12, wherein the encapsulation layer has a single-layer structure made of an inorganic material, or a multi-layer structure made of multiple inorganic layers that are sequentially stacked, or a structure made of an inorganic layer, an organic layer and an inorganic layer that are continuously stacked.

17. The light emitting display device according to claim 1, wherein a total thickness of the first layer, the second layer and the third layer of the cathode electrode is 450 Å to 700 Å.
